(19) United States
(12) Patent Application Publication
(10) Pub. No.: US 2007/0103066 A1
(43) Pub. Date: May 10, 2007

(54) Stacked OLEDs with a reflective conductive layer

(76) Inventors: Brian W. D'Andrade, Westampton, NJ (US); Richard H. Hewitt, Ewing, NJ (US); Kamala Rajan, Newtown, PA (US); Vadim Adamovich, Lawrenceville, NJ (US)

Correspondence Address: KENYON & KENYON LLP, 1500 K STREET N.W., SUITE 700, WASHINGTON, DC, 20005, US

(21) Appl. No.: 11/266,181

(22) Filed: Nov. 4, 2005

(51) Int. Cl. H01J 1/62

(52) U.S. Cl. 313/506; 313/504

(57) ABSTRACT

The present invention provides an OLED comprising two or more organic emissive layers electrically connected with a reflective conductive layer.

The claimed invention was made by, on behalf of, and/or in connection with one or more of the following parties to a joint university corporation research agreement: Princeton University, The University of Southern California, and the Universal Display Corporation. The agreement was in effect on and before the date the claimed invention was made, and the claimed invention was made as a result of activities undertaken within the scope of the agreement.

### FIELD OF THE INVENTION

The present invention relates to organic light emitting devices (OLEDs), and more specifically to stacked OLEDs connected with a reflective conductive layer.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules. In general, a small molecule has a well-defined chemical formula with a single molecular weight, whereas a polymer has a chemical formula and a molecular weight that may vary from molecule to molecule. As used herein, “organic” includes metal complexes of hydrocarbyl and heteroatom-substituted hydrocarbyl ligands.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

OLED devices are generally (but not always) intended to emit light through at least one of the electrodes, and one or more transparent electrodes may be useful in an organic opto-electronic devices. For example, a transparent electrode material, such as indium tin oxide (ITO), may be used as the bottom electrode. A transparent top electrode, such as disclosed in U.S. Pat. Nos. 5,703,436 and 5,707,745, which are incorporated by reference in their entireties, may also be used. For a device intended to emit light only through the bottom electrode, the top electrode does not need to be transparent, and may be comprised of a thick and reflective metal layer having a high electrical conductivity. Similarly, for a device intended to emit light only through the top electrode, the bottom electrode may be opaque and/or reflective. Where an electrode does not need to be transparent, using a thicker layer may provide better conductivity, and using a reflective electrode may increase the amount of light emitted through the other electrode, by reflecting light back towards the transparent electrode. Fully transparent devices may also be fabricated, where both electrodes are transparent. Side emitting OLEDs may also be fabricated, and one or both electrodes may be opaque or reflective in such devices.

As used herein, “top” means furthest away from the substrate, while “bottom” means closest to the substrate. For example, for a device having two electrodes, the bottom electrode is the electrode closest to the substrate, and is generally the first electrode fabricated. The bottom electrode has two surfaces, a bottom surface closest to the substrate, and a top surface further away from the substrate. Where a first layer is described as “disposed over” a second layer, the first layer is disposed further away from substrate. There may be other layers between the first and second layer, unless it is specified that the first layer is “in physical contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

### SUMMARY OF THE INVENTION

In one embodiment, the present invention provides an OLED comprising a first organic stack including a first organic emissive layer; a second organic stack including a second organic emissive layer; and a reflective conductive layer disposed between, and electrically connected to, the first organic stack and the second organic stack. The reflective conductive layer can be a cathode, an anode, or it can simultaneously be a cathode and an anode.

In one embodiment, the first organic stack, the reflective connecting conductive layer, and the second organic stack are deposited over a transparent substrate. Preferably, the reflective conductive layer is deposited by vacuum thermal evaporation.

In another embodiment, the reflective conductive layer is a substrate, and the first and second organic stacks are deposited on opposite faces of the reflective connecting conductive layer.

In yet another embodiment, the device further comprises a substrate, both faces of which includes a reflective conductive layer. The first organic stack and the second organic stack are deposited on opposite faces of the substrate. In this embodiment, the substrate can be two electrically connected substrate layers.

In a preferred embodiment, the first and second organic stacks each comprise a transparent end electrode. In this embodiment, the device can emit light in 4π steradians.

The organic stacks can be connected in series or in parallel. The stacks can be independently addressable.

In one embodiment, the device has a high fill factor. This embodiment is particularly useful for two-sided displays. Embodiments of the present invention can also be useful for illumination purposes.

In another embodiment, the present invention provides an OLED comprising a first organic stack including a first organic emissive layer; a second organic stack including a second organic emissive layer; and a metal film conductive layer disposed between, and electrically connected to, the first organic stack and the second organic stack. Preferably, the metal film is smooth.

In one embodiment, the present invention provides a method for making the OLEDs described above by fabricating a first organic stack over a substrate; depositing a reflective conductive layer over the first organic stack; and fabricating a second organic stack over the reflective conductive layer. In a preferred embodiment, the conductive layer is a metal film deposited by vacuum thermal evaporation.

In another embodiment, the present invention provides a method for making the OLEDs described above by fabricating a first organic stack on one face of a reflective conductive layer and fabricating a second organic stack on the opposite face of the reflective conductive layer.

In yet another embodiment, the present invention provides a method for making the OLEDs described above by fabricating a first organic stack on a reflective conductive layer attached to one face of a substrate and fabricating a second organic stack on a reflective conductive layer attached the opposite face of the substrate.

### BRIEF DESCRIPTION OF THE DRAWINGS

FIG. 1 shows an organic light emitting device having separate electron transport, hole transport, and emissive layers, as well as other layers.

FIG. 2 shows an inverted organic light emitting device that does not have a separate electron transport layer.

FIG. 3 shows a device with a reflective conductive layer.

FIG. 4 shows a vertically stacked device that is serially connected by a reflective conductive layer. The conductive layer acts as both a cathode and an anode.

FIG. 5 shows a vertically stacked device that is electrically connected by a reflective conductive layer.

FIG. 6 shows a stacked device that is electrically connected by a reflective conductive layer.

FIG. 7 shows a stacked device that is electrically connected by a reflective conductive layer that has a direct external connection.

FIG. 8 shows electroluminescence at 10 mA/cm² from a green top emitting organic stack and blue bottom emitting organic stack in a vertically stacked device with a reflective conductive layer.

FIG. 9 shows the external quantum efficiency versus current density for the green top emitting and blue bottom emitting device.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

As used herein, an electrode is a conductive layer that is externally connected. That is, a connection exterior to the device provides direct electrical access to the electrode. In the context of an OLED, cathodes inject electrons into a device, and anodes inject holes. Layers that do not have direct external connections may be referred to as “charge generation layers”. Anodes and cathodes may each be electrodes or charge generation layers. A charge generation layer may be an anode and a cathode at the same time. That is, it may be simultaneously an anode with respect to one organic layer and a cathode for another organic layer.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 1, 4-6 (1999) (“Baldo-II”), which are incorporated by reference in their entireties. Phosphorescence may be referred to as a “forbidden” transition because the transition requires a change in spin states, and quantum mechanics indicates that such a transition is not favored. As a result, phosphorescence generally occurs in a time frame exceeding at least 10 milliseconds, and typically greater than 100 milliseconds. If the natural radiative lifetime of phosphorescence is too long, triplets may decay by a non-radiative mechanism, such that no light is emitted. Organic phosphorescence is also often observed in molecules containing heteroatoms with unshared pairs of electrons at very low temperatures. 2,2′-bipyridine is such a molecule. Non-radiative decay mechanisms are typically temperature dependent, such that an organic material that exhibits phosphorescence at liquid nitrogen temperatures typically does not exhibit phosphorescence at room temperature. But, as demonstrated by Baldo, this problem may be addressed by selecting phosphorescent compounds that do phosphoresce at room temperature. Representative emissive layers include doped or undoped phosphorescent organometallic materials such as disclosed in U.S. Pat. Nos. 6,303,238 and 6,310,360; U.S. Patent Application Publication Nos. 2002-0034656; 2002-0182441; 2003-0072964; and WO-02/074015.

Generally, the excitons in an OLED are believed to be created in a ratio of about 3:1, i.e., approximately 75% triplets and 25% singlets. See, Adachi et al., “Nearly 100% Internal Phosphorescent Efficiency In An Organic Light Emitting Device,” J. Appl. Phys., 90, 5048 (2001), which is incorporated by reference in its entirety. In many cases, singlet excitons may readily transfer their energy to triplet excited states via “intersystem crossing,” whereas triplet excitons may not readily transfer their energy to singlet excited states. As a result, 100% internal quantum efficiency is theoretically possible with phosphorescent OLEDs. In a fluorescent device, the energy of triplet excitons is generally lost to radiationless decay processes that heat-up the device, resulting in much lower internal quantum efficiencies. OLEDs utilizing phosphorescent materials that emit from triplet excited states are disclosed, for example, in U.S. Pat. No. 6,303,238, which is incorporated by reference in its entirety.

Phosphorescence may be preceded by a transition from a triplet excited state to an intermediate non-triplet state from which the emissive decay occurs. For example, organic molecules coordinated to lanthanide elements often phosphoresce from excited states localized on the lanthanide metal. However, such materials do not phosphoresce directly from a triplet excited state but instead emit from an atomic excited state centered on the lanthanide metal ion. The europium diketonate complexes illustrate one group of these types of species.

Phosphorescence from triplets can be enhanced over fluorescence by confining, preferably through bonding, the organic molecule in close proximity to an atom of high atomic number. This phenomenon, called the heavy atom effect, is created by a mechanism known as spin-orbit coupling. Such a phosphorescent transition may be observed from an excited metal-to-ligand charge transfer (MLCT) state of an organometallic molecule such as tris(2-phenylpyridine)iridium(III).

As used herein, the term “triplet energy” refers to an energy corresponding to the highest energy feature discernable in the phosphorescence spectrum of a given material. The highest energy feature is not necessarily the peak having the greatest intensity in the phosphorescence spectrum, and could, for example, be a local maximum of a clear shoulder on the high energy side of such a peak.

The term “organometallic” as used herein is as generally understood by one of ordinary skill in the art and as given, for example, in “Inorganic Chemistry” (2nd Edition) by Gary L. Miessler and Donald A. Tarr, Prentice Hall (1998). Thus, the term organometallic refers to compounds which have an organic group bonded to a metal through a carbon-metal bond. This class does not include per se coordination compounds, which are substances having only donor bonds from heteroatoms, such as metal complexes of amines, halides, pseudohalides (CN, etc.), and the like. In practice organometallic compounds generally comprise, in addition to one or more carbon-metal bonds to an organic species, one or more donor bonds from a heteroatom. The carbon-metal bond to an organic species refers to a direct bond between a metal and a carbon atom of an organic group, such as phenyl, alkyl, alkenyl, etc., but does not refer to a metal bond to an “inorganic carbon,” such as the carbon of CN or CO.

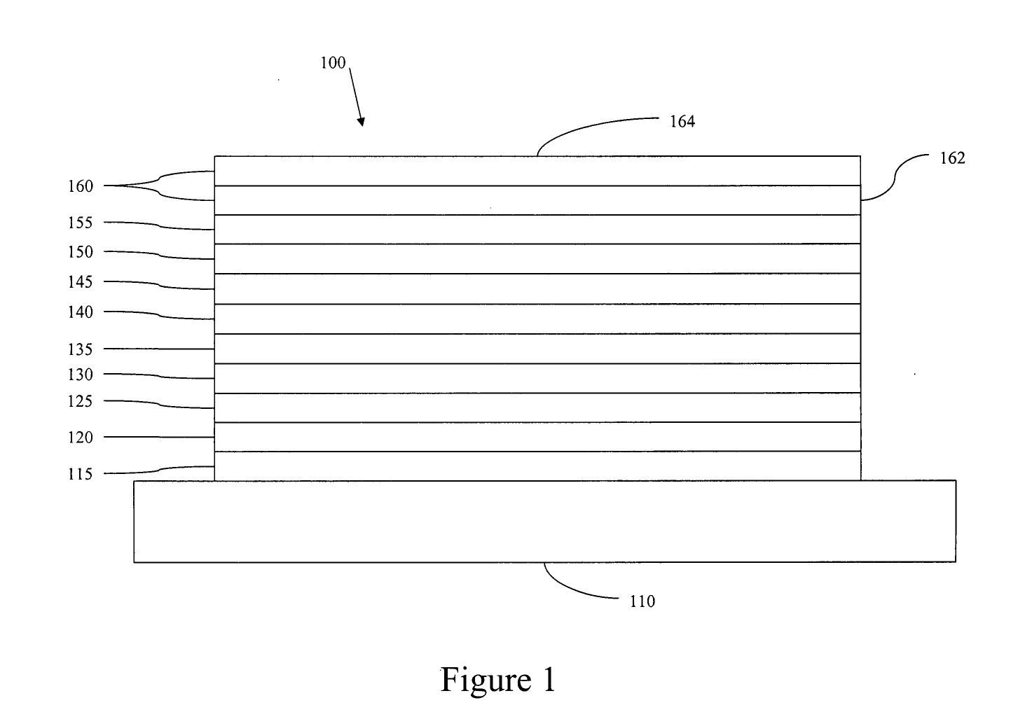

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, and a cathode 160. Cathode 160 is a compound cathode having a first conductive layer 162 and a second conductive layer 164. Device 100 may be fabricated by depositing the layers described, in order.

Substrate 110 may be any suitable substrate that provides desired structural properties. Substrate 110 may be flexible or rigid. Substrate 110 may be transparent, translucent or opaque. Plastic and glass are examples of preferred rigid substrate materials. Plastic and metal foils are examples of preferred flexible substrate materials. Substrate 110 may be a semiconductor material in order to facilitate the fabrication of circuitry. For example, substrate 110 may be a silicon wafer upon which circuits are fabricated, capable of controlling OLEDs subsequently deposited on the substrate. Other substrates may be used. The material and thickness of substrate 110 may be chosen to obtain desired structural and optical properties.

Anode 115 may be any suitable anode that is sufficiently conductive to transport holes to the organic layers. The material of anode 115 preferably has a work function higher than about 4 eV (a “high work function material”). Preferred anode materials include conductive metal oxides, such as indium tin oxide (ITO) and indium zinc oxide (IZO), aluminum zinc oxide (AlZnO), and metals. Anode 115 (and substrate 110) may be sufficiently transparent to create a bottom-emitting device. A preferred transparent substrate and anode combination is commercially available ITO (anode) deposited on glass or plastic (substrate). A flexible and transparent substrate-anode combination is disclosed in U.S. Pat. Nos. 5,844,363 and 6,602,540 B2, which are incorporated by reference in their entireties. Anode 115 may be opaque and/or reflective. A reflective anode 115 may be preferred for some top-emitting devices, to increase the amount of light emitted from the top of the device. The material and thickness of anode 115 may be chosen to obtain desired conductive and optical properties. Where anode 115 is transparent, there may be a range of thickness for a particular material that is thick enough to provide the desired conductivity, yet thin enough to provide the desired degree of transparency. Other anode materials and structures may be used.

Hole transport layer 125 may include a material capable of transporting holes. Hole transport layer 130 may be intrinsic (undoped), or doped. Doping may be used to enhance conductivity. α-NPD and TPD are examples of intrinsic hole transport layers. An example of a p-doped hole transport layer is m-MTDATA doped with F₄-TCNQ at a molar ratio of 50:1, as disclosed in United States Patent Application Publication No. 2003-02309890 to Forrest et al., which is incorporated by reference in its entirety. Other hole transport layers may be used.

Emissive layer 135 may include an organic material capable of emitting light when a current is passed between anode 115 and cathode 160. Preferably, emissive layer 135 contains a phosphorescent emissive material, although fluorescent emissive materials may also be used. Phosphorescent materials are preferred because of the higher luminescent efficiencies associated with such materials. Emissive layer 135 may also comprise a host material capable of transporting electrons and/or holes, doped with an emissive material that may trap electrons, holes, and/or excitons, such that excitons relax from the emissive material via a photoemissive mechanism. Emissive layer 135 may comprise a single material that combines transport and emissive properties. Whether the emissive material is a dopant or a major constituent, emissive layer 135 may comprise other materials, such as dopants that tune the emission of the emissive material. Emissive layer 135 may include a plurality of emissive materials capable of, in combination, emitting a desired spectrum of light. Examples of phosphorescent emissive materials include Ir(ppy)₃. Examples of fluorescent emissive materials include DCM and DMQA. Examples of host materials include Alq₃, CBP and mCP. Examples of emissive and host materials are disclosed in U.S. Pat. No. 6,303,238 to Thompson et al., which is incorporated by reference in its entirety. Emissive material may be included in emissive layer 135 in a number of ways. For example, an emissive small molecule may be incorporated into a polymer. This may be accomplished by several ways: by doping the small molecule into the polymer either as a separate and distinct molecular species; or by incorporating the small molecule into the backbone of the polymer, so as to form a co-polymer; or by bonding the small molecule as a pendant group on the polymer. Other emissive layer materials and structures may be used. For example, a small molecule emissive material may be present as the core of a dendrimer.

Many useful emissive materials include one or more ligands bound to a metal center. A ligand may be referred to as “photoactive” if it contributes directly to the photoactive properties of an organometallic emissive material. A “photoactive” ligand may provide, in conjunction with a metal, the energy levels from which and to which an electron moves when a photon is emitted. Other ligands may be referred to as “ancillary.” Ancillary ligands may modify the photoactive properties of the molecule, for example by shifting the energy levels of a photoactive ligand, but ancillary ligands do not directly provide the energy levels involved in light emission. A ligand that is photoactive in one molecule may be ancillary in another. These definitions of photoactive and ancillary are intended as non-limiting theories.

Electron transport layer 145 may include a material capable of transporting electrons. Electron transport layer 145 may be intrinsic (undoped), or doped. Doping may be used to enhance conductivity. Alq₃ is an example of an intrinsic electron transport layer. An example of an n-doped electron transport layer is BPhen doped with Li at a molar ratio of 1:1, as disclosed in United States Patent Application Publication No. 2003-02309890 to Forrest et al., which is incorporated by reference in its entirety. Other electron transport layers may be used.

The charge carrying component of the electron transport layer may be selected such that electrons can be efficiently injected from the cathode into the LUMO (Lowest Unoccupied Molecular Orbital) energy level of the electron transport layer. The “charge carrying component” is the material responsible for the LUMO energy level that actually transports electrons. This component may be the base material, or it may be a dopant. The LUMO energy level of an organic material may be generally characterized by the electron affinity of that material and the relative electron injection efficiency of a cathode may be generally characterized in terms of the work function of the cathode material. This means that the preferred properties of an electron transport layer and the adjacent cathode may be specified in terms of the electron affinity of the charge carrying component of the ETL and the work function of the cathode material. In particular, so as to achieve high electron injection efficiency, the work function of the cathode material is preferably not greater than the electron affinity of the charge carrying component of the electron transport layer by more than about 0.75 eV, more preferably, by not more than about 0.5 eV. Similar considerations apply to any layer into which electrons are being injected.

Cathode 160 may be any suitable material or combination of materials known to the art, such that cathode 160 is capable of conducting electrons and injecting them into the organic layers of device 100. Cathode 160 may be transparent or opaque, and may be reflective. Metals and metal oxides are examples of suitable cathode materials. Cathode 160 may be a single layer, or may have a compound structure. FIG. 1 shows a compound cathode 160 having a thin metal layer 162 and a thicker conductive metal oxide layer 164. In a compound cathode, preferred materials for the thicker layer 164 include ITO, IZO, and other materials known to the art. U.S. Pat. Nos. 5,703,436, 5,707,745, 6,548,956 B2 and 6,576,134 B2, which are incorporated by reference in their entireties, disclose examples of cathodes including compound cathodes having a thin layer of metal such as Mg:Ag with an overlying transparent, electrically-conductive, sputter-deposited ITO layer. The part of cathode 160 that is in contact with the underlying organic layer, whether it is a single layer cathode 160, the thin metal layer 162 of a compound cathode, or some other part, is preferably made of a material having a work function lower than about 4 eV (a “low work function material”). Other cathode materials and structures may be used.

Blocking layers may be used to reduce the number of charge carriers (electrons or holes) and/or excitons that leave the emissive layer. An electron blocking layer 130 may be disposed between emissive layer 135 and the hole transport layer 125, to block electrons from leaving emissive layer 135 in the direction of hole transport layer 125. Similarly, a hole blocking layer 140 may be disposed between emissive layer 135 and electron transport layer 145, to block holes from leaving emissive layer 135 in the direction of electron transport layer 145. Blocking layers may also be used to block excitons from diffusing out of the emissive layer. The theory and use of blocking layers is described in more detail in U.S. Pat. No. 6,097,147 and United States Patent Application Publication No. 2003-02309890 to Forrest et al., which are incorporated by reference in their entireties.

As used herein, and as would be understood by one skilled in the art, the term “blocking layer” means that the layer provides a barrier that significantly inhibits transport of charge carriers and/or excitons through the device, without suggesting that the layer necessarily completely blocks the charge carriers and/or excitons. The presence of such a blocking layer in a device may result in substantially higher efficiencies as compared to a similar device lacking a blocking layer. Also, a blocking layer may be used to confine emission to a desired region of an OLED.

Generally, injection layers are comprised of a material that may improve the injection of charge carriers from one layer, such as an electrode or an organic layer, into an adjacent organic layer. Injection layers may also perform a charge transport function. In device 100, hole injection layer 120 may be any layer that improves the injection of holes from anode 115 into hole transport layer 125. CuPc is an example of a material that maybe used as a hole injection layer from an ITO anode 115, and other anodes. In device 100, electron injection layer 150 may be any layer that improves the injection of electrons into electron transport layer 145. LiF/Al is an example of a material that may be used as an electron injection layer into an electron transport layer from an adjacent layer. Other materials or combinations of materials may be used for injection layers. Depending upon the configuration of a particular device, injection layers may be disposed at locations different than those shown in device 100. More examples of injection layers are provided in U.S. patent application Ser. No. 09/931,948 to Lu et al., which is incorporated by reference in its entirety. A hole injection layer may comprise a solution deposited material, such as a spin-coated polymer, e.g., PEDOT:PSS, or it may be a vapor deposited small molecule material, e.g., CuPc or MTDATA.

A hole injection layer (HIL) may planarize or wet the anode surface so as to provide efficient hole injection from the anode into the hole injecting material. A hole injection layer may also have a charge carrying component having HOMO (Highest Occupied Molecular Orbital) energy levels that favorably match up, as defined by their herein-described relative ionization potential (IP) energies, with the adjacent anode layer on one side of the HIL and the hole transporting layer on the opposite side of the HIL. The “charge carrying component” is the material responsible for the HOMO energy level that actually transports holes. This component may be the base material of the HIL, or it may be a dopant. Using a doped HIL allows the dopant to be selected for its electrical properties, and the host to be selected for morphological properties such as wetting, flexibility, toughness, etc. Preferred properties for the HIL material are such that holes can be efficiently injected from the anode into the HIL material. In particular, the charge carrying component of the HIL preferably has an IP not more than about 0.7 eV greater that the IP of the anode material. More preferably, the charge carrying component has an IP not more than about 0.5 eV greater than the anode material. Similar considerations apply to any layer into which holes are being injected. HIL materials are further distinguished from conventional hole transporting materials that are typically used in the hole transporting layer of an OLED in that such HIL materials may have a hole conductivity that is substantially less than the hole conductivity of conventional hole transporting materials. The thickness of the HIL of the present invention may be thick enough to help planarize or wet the surface of the anode layer. For example, an HIL thickness of as little as 10 nm may be acceptable for a very smooth anode surface. However, since anode surfaces tend to be very rough, a thickness for the HIL of up to 50 nm may be desired in some cases.

A protective layer may be used to protect underlying layers during subsequent fabrication processes. For example, the processes used to fabricate metal or metal oxide top electrodes may damage organic layers, and a protective layer may be used to reduce or eliminate such damage. In device 100, protective layer 155 may reduce damage to underlying organic layers during the fabrication of cathode 160. Preferably, a protective layer has a high carrier mobility for the type of carrier that it transports (electrons in device 100), such that it does not significantly increase the operating voltage of device 100. CuPc, BCP, and various metal phthalocyanines are examples of materials that may be used in protective layers. Other materials or combinations of materials may be used. The thickness of protective layer 155 is preferably thick enough that there is little or no damage to underlying layers due to fabrication processes that occur after organic protective layer 160 is deposited, yet not so thick as to significantly increase the operating voltage of device 100. Protective layer 155 may be doped to increase its conductivity. For example, a CuPc or BCP protective layer 160 may be doped with Li. A more detailed description of protective layers may be found in U.S. patent application Ser. No. 09/931,948 to Lu et al., which is incorporated by reference in its entirety.

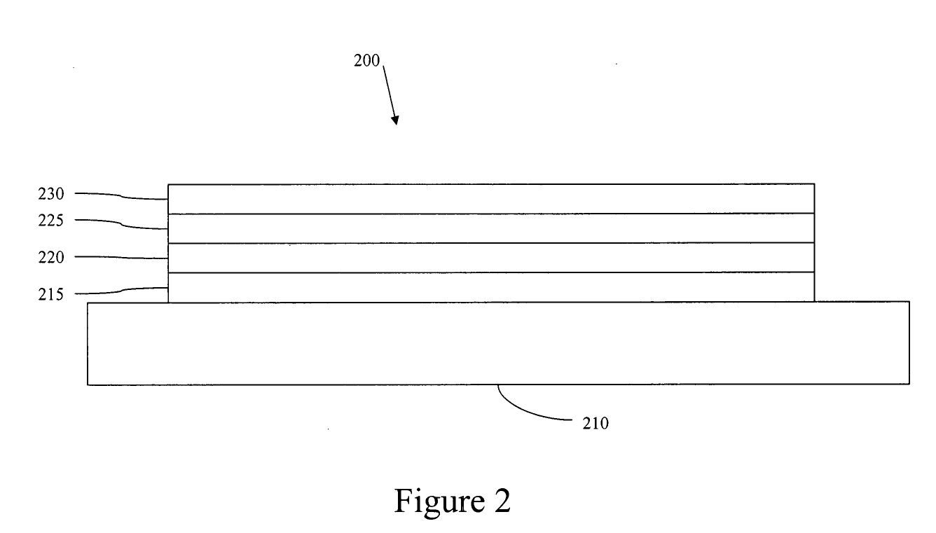

FIG. 2 shows an inverted OLED 200. The device includes a substrate 210, an cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190, Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. patent application Ser. No. 10/233,470, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJP. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

The molecules disclosed herein may be substituted in a number of different ways without departing from the scope of the invention. For example, substituents may be added to a compound having three bidentate ligands, such that after the substituents are added, one or more of the bidentate ligands are linked together to form, for example, a tetradentate or hexadentate ligand. Other such linkages may be formed. It is believed that this type of linking may increase stability relative to a similar compound without linking, due to what is generally understood in the art as a “chelating effect.”

Devices fabricated in accordance with embodiments of the invention may be incorporated into a wide variety of consumer products, including flat panel displays, computer monitors, televisions, billboards, lights for interior or exterior illumination and/or signaling, heads up displays, fully transparent displays, flexible displays, laser printers, telephones, cell phones, personal digital assistants (PDAs), laptop computers, digital cameras, camcorders, viewfinders, micro-displays, vehicles, a large area wall, theater or stadium screen, or a sign. Various control mechanisms may be used to control devices fabricated in accordance with the present invention, including passive matrix and active matrix. Many of the devices are intended for use in a temperature range comfortable to humans, such as 18 degrees C. to 30 degrees C., and more preferably at room temperature (20-25 degrees C.).

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In one embodiment, the present invention provides an OLED comprising a first organic stack including a first organic emissive layer; a second organic stack including a second organic emissive layer; and a reflective conductive layer disposed between, and electrically connected to, the first organic stack and the second organic stack. An organic stack is one or more organic layers at least one of which is an organic emissive layer. Each organic stack can include one or more layers such as injection layers, transport layers, and blocking layers. In a preferred embodiment, each of the first and second organic stacks include a hole injection layer, a hole transport layer, an organic emissive layer, and an electron transport layer.

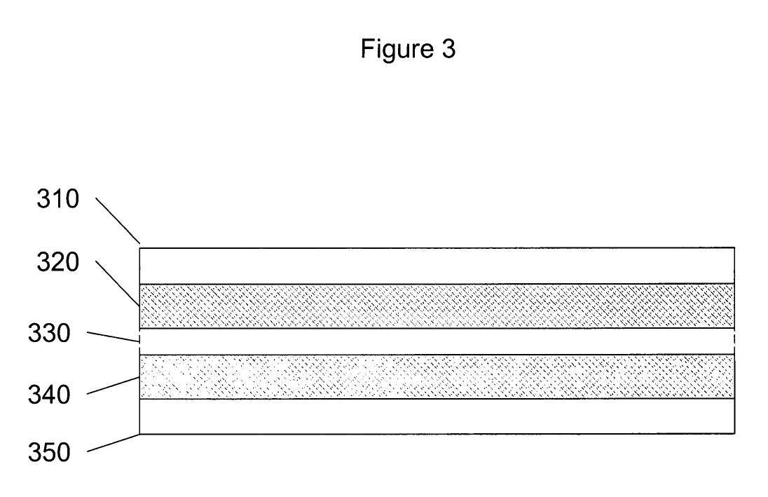

FIG. 3 shows an embodiment of the present invention. Reflective conductive layer 330 is disposed between and electrically connected to first organic stack 320 and second organic stack 340. The device further comprises transparent electrodes 310 and 350. Reflective conductive layer 330 may comprise a deposited layer, a reflective substrate, or a substrate with reflective layers deposited on both sides.

The reflective conductive layer can be a cathode, an anode, or it can simultaneously be a cathode and an anode. When the reflective conductive layer is simultaneously a cathode and an anode, it may be a cathode for one organic stack and an anode for another organic stack. When acting as an anode for an organic stack, the reflective conductive layer may inject holes; when acting as a cathode it may inject electrons.

In the context of the present invention, a “reflective” layer is one that reflects at least about 75% of visible light and transmits at most about 5% of visible light. Visible light has a wavelength of about 380 to about 780 nm. The low level of transmitted light is particularly important for two-sided display applications where reducing the amount of light contamination between the two sides is desirable. Preferably, the reflective conductive layer reflects at least about 80% of visible light and transmits virtually no visible light. The remaining visible light is absorbed by the layer.

In one embodiment, the present invention provides a stacked OLED in which the reflective conductive layer is a metal film. Thus, the present invention provides an OLED comprising a first organic stack including a first organic emissive layer; a second organic stack including a second organic emissive layer; and a metal film reflective conductive layer disposed between, and electrically connected to, the first organic stack and the second organic stack.

The metal film reflective conductive layer is thick enough to reduce or prevent an electric field from extending between the first and second organic stacks. Metal films can be deposited by sputtering techniques, but depositing conductive oxides by sputtering techniques can form spikes in the metal film layer, which can short the device. Furthermore, sputtering techniques often result in low resolution of shadow masks as compared to high-vacuum techniques. The metal films of the present invention can be deposited by vacuum thermal evaporation or other conventional thin film deposition techniques, such as e-beam printing. Preferred deposition techniques, such as vacuum thermal evaporation, result in a smooth metal film. Preferably, the metal film has a maximum spike length of about 100 Å, more preferably about 10 Å. As will be understood by one skilled in the art, “spike length” refers to the measurement of a raised feature from the point of the feature closest to the substrate to the point farthest from the substrate. Another advantage of the present invention is that it does not require a doped connecting electrode, which may require additional materials and/or equipment for fabrication.

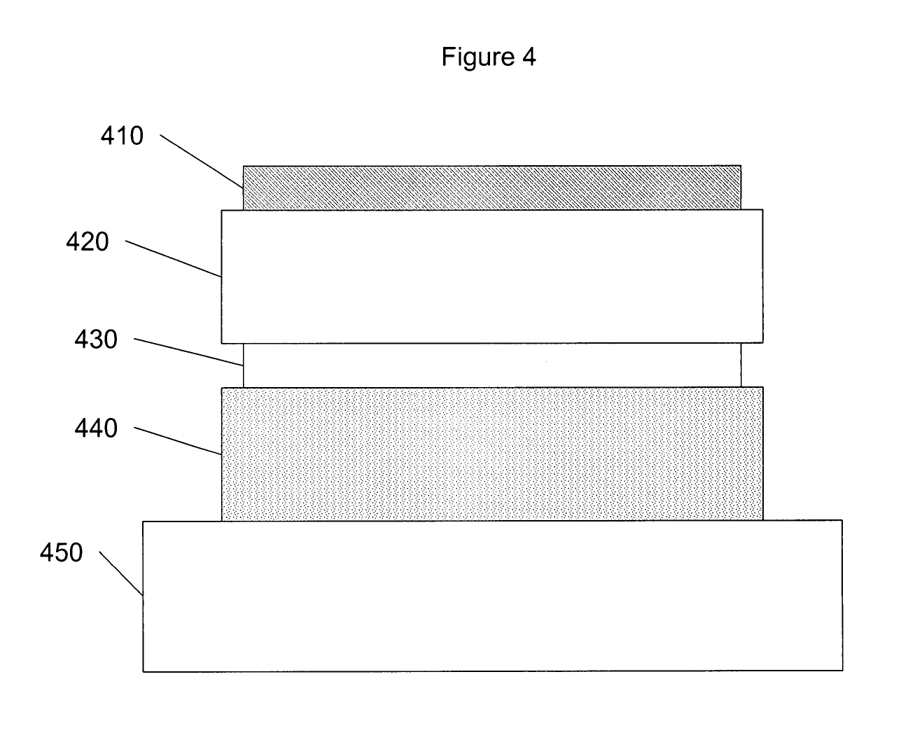

In one embodiment, the first organic stack, the reflective conductive layer, and the second organic stack are deposited over a transparent substrate. FIG. 4 shows an example of such a configuration. First organic stack 440, reflective conductive layer 430, and second organic stack 420 are deposited on transparent substrate 450. Reflective conductive layer 430 may be disposed between and electrically connected first organic stack 440 and second organic stack 420. Preferably, reflective conductive layer 430 is deposited by vacuum thermal evaporation. Transparent electrode 410 is disposed over organic stacks 420 and 440 and reflective conductive layer 430.

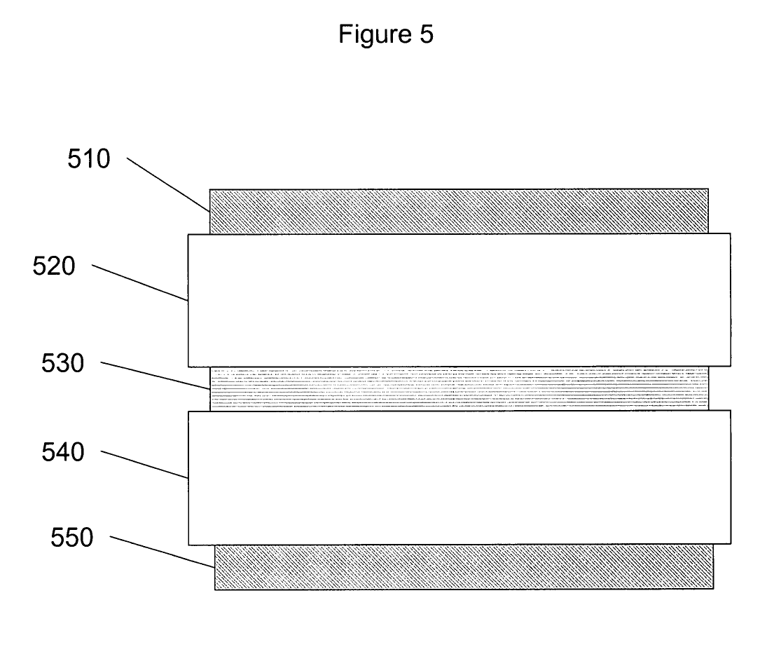

In another embodiment, the reflective conductive layer is a substrate. A substrate is a pre-existing layer; it is not deposited onto another layer. Thus, in this embodiment, the first and second organic stacks are deposited on opposite faces of a pre-existing reflective conductive layer. For example, referring to FIG. 5, organic stacks 520 and 540 may be deposited on either side of reflective conductive layer 530. Transparent electrodes 510 and 550 may be deposited on either side of the device.

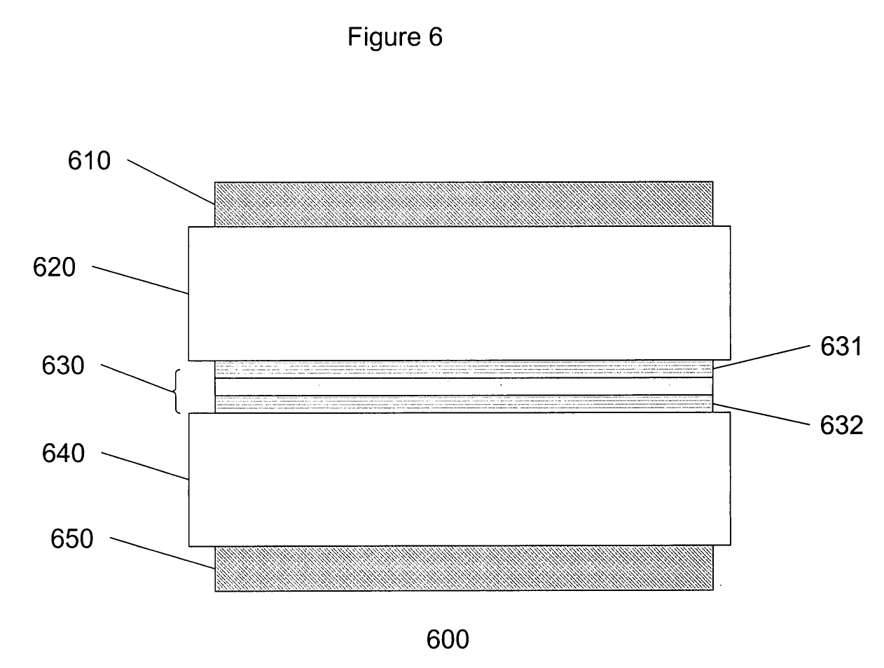

FIG. 6 shows another embodiment of the present invention. Device 600 comprises substrate 630, each face of which includes a reflective conductive layer 631 and 632. First organic stack 620 and second organic stack 640 are deposited on opposite faces of substrate 630. Substrate 630 may be two electrically connected substrate layers. In other words, first organic stack 620 may be deposited onto a first substrate including a reflective conductive layer. Second organic stack 640 may be deposited onto a second substrate including a reflective conductive layer. Then, the two substrates can be attached to one another by methods known in the art. Transparent electrodes 610 and 650 may then be deposited on either side of the structure. Such a structure may be desirable, for example to allow organic stacks 620 and 640 to be independently addressable.

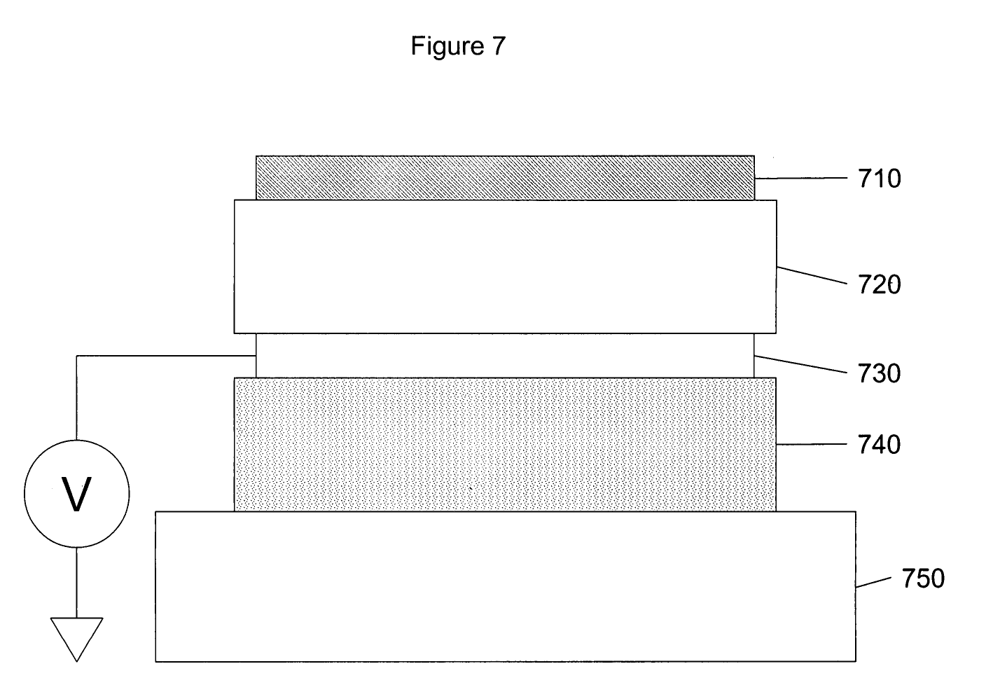

In some embodiments, the reflective conductive layer may be an electrode. For example, in FIG. 7, reflective conductive layer 730 is disposed between organic stacks 720 and 740. Reflective conductive layer 730 is directly externally connected, such that a voltage may be provided to the layer. Electrodes 710 and 750 may also be connected to an external voltage (not shown).

In many embodiments, the order in which layers are deposited may be structurally significant. In some cases deposition of a layer will cause damage to the underlying layer. Often, this damage creates a damage region which usefully enhances charge carrier transport. Deposition of layers in different orders can result in damage regions with varying properties, only some of which will enhance charge carrier transport. Other damage regions may inhibit transport, reducing the efficiency of the device. It may therefore be important to deposit layers in an order which results in an efficient damage region. Such damage regions are disclosed in U.S. Pat. No. 6,420,031 to Parthasarathy et. al., incorporated herein by reference in its entirety.

Embodiments having a deposited reflective conductive layer, such as those illustrated by FIGS. 3, 4, and 7, may be particularly preferred because they can be fabricated without flipping the substrate, thus simplifying fabrication. Structurally, these embodiments are different from other embodiments because the organic stacks and the reflective conductive layer are disposed on the same side of the substrate.

In a preferred embodiment, the first and second organic stacks each comprise a transparent end electrode. Thus, one end of each organic stack contacts the conductive reflective layer and the other end of the organic stack contacts a transparent end electrode. In this embodiment, the device can emit light in 4π steradians, that is, in all directions.

The organic stacks can be connected in series or in parallel. The stacks can be independently addressable. By making the stacks independently addressable, the device is particularly suitable for a two-sided display. Thus, two viewers facing each other can read from the same display panel. Or the device can be incorporated into the display for a clam-shell type cell phone, where a side of the display can also be used as a mirror. Other useful applications will be readily apparent to one skilled in the art.

In one embodiment, the device has a high fill factor. Specifically, a monochrome device according to the present invention preferably has a fill factor of at least about 50% on both sides of the reflective conductive layer. A multi-color device according to the present invention, e.g., a device with red, green, and blue sub-pixels, preferably has a fill factor of at least about 35% on both sides of the reflective connecting electrode.

In another embodiment, the device has high optical power. The optical power per unit area of an OLED is increased when OLEDs are vertically stacked, but when too many OLED unites are stacked, optical losses are incurred because the gain in brightness is offset by reduced efficiency. Accordingly, an optimum number of stacked OLED units achieves high efficiency and high brightness. In the present invention, the optical power per unit area can be doubled because the optimum number of stacked OLEDs can be used on both sides of the conductive reflective layer. This embodiment is particularly useful for illumination purposes, such as, for example, recessed overhead lighting for a room.

Similarly, the devices of the present invention can achieve a high external quantum efficiency. The efficiency of each organic stack can be optimized using known techniques in the art. Efficiency can be improved, for example, by improving out-coupling by incorporating features such as a mesa structure as described in U.S. Pat. No. 6,091,195 to Forrest et al., and/or a pit structure as described in U.S. Pat. No. 5,834,893 to Bulovic et al. Other methods of improving out-coupling can also be used. There are device structures having better out-coupling efficiencies than the devices described herein, and it is anticipated that improvements to out-coupling efficiency will be made over time. Such improvements would enhance external quantum efficiency. By optimizing the efficiency of both organic stacks, the overall efficiency of the device is doubled compared to similar OLEDs without a reflective connecting electrode.

In one embodiment, the present invention provides a method for making the OLEDs described above by fabricating a first organic stack over a substrate; depositing a reflective conductive layer over the first organic stack; and fabricating a second organic stack over the reflective conductive layer. In a preferred embodiment, the reflective conductive layer is a metal film deposited by vacuum thermal evaporation. Other standard techniques can be used, particularly standard high-vacuum techniques and e-beam printing.

In another embodiment, the present invention provides a method for making the OLEDs described above by fabricating a first organic stack on one face of a reflective conductive layer and fabricating a second organic stack on the opposite face of the layer.

In yet another embodiment, the present invention provides a method for making the OLEDs described above by fabricating a first organic stack on a reflective conductive layer attached to one face of a substrate and fabricating a second organic stack on a reflective conductive layer attached the opposite face of the substrate.

It is understood that the various embodiments described herein are by way of example only, and are not intended to limit the scope of the invention. For example, many of the materials and structures described herein may be substituted with other materials and structures without deviating from the spirit of the invention. It is understood that various theories as to why the invention works are not intended to be limiting. For example, theories relating to charge transfer are not intended to be limiting.

Material Definitions:
As used herein, abbreviations refer to materials as follows:
CBP: 4,4′-N,N-dicarbazole-biphenyl
m-MTDATA 4,4′,4″-tris(3-methylphenylphenlyamino)triphenylamine
Alq₃: 8-tris-hydroxyquinoline aluminum
Bphen: 4,7-diphenyl-1,10-phenanthroline
n-BPhen: n-doped BPhen (doped with lithium)
F₄-TCNQ: tetrafluoro-tetracyano-quinodimethane
p-MTDATA: p-doped m-MTDATA (doped with F₄-TCNQ)
Ir(ppy)₃: tris(2-phenylpyridine)-iridium
Ir(ppz)₃: tris(1-phenylpyrazoloto,N,C(2′)iridium(III)
BCP: 2,9-dimethyl-4,7-diphenyl-1,10-phenanthroline
TAZ: 3-phenyl-4-(1′-naphthyl)-5-phenyl-1,2,4-triazole
CuPc: copper phthalocyanine.
ITO: indium tin oxide
NPD: N,N′-diphenyl-N-N′-di(1-naphthyl)-benzidine
TPD: N,N′-diphenyl-N-N′-di(3-toly)-benzidine
BAlq: aluminum(III)bis(2-methyl-8-hydroxyquinolinato)4-phenylphenolate
mCP: 1,3-N,N-dicarbazole-benzene
DCM: 4-(dicyanoethylene)-6-(4-dimethylaminostyryl-2-methyl)-4H-pyran
DMQA: N,N′-dimethylquinacridone
PEDOT:PSS: an aqueous dispersion of poly(3,4-ethylenedioxythiophene) with polystyrenesulfonate (PSS)

Experimental: Specific representative embodiments of the invention will now be described, including how such embodiments may be made. It is understood that the specific methods, materials, conditions, process parameters, apparatus and the like do not necessarily limit the scope of the invention.

An embodiment of the present invention is constructed as follows:

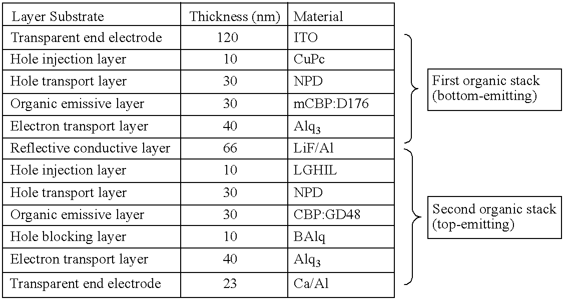

The reflective conductive layer is 65 nm of Al deposited on 1 nm of LiF. The second (top) transparent electrode is 20 nm of Ca and 3 nm of Al. Other more transparent top electrodes can be used, such as ITO. The first (bottom) transparent electrode is ITO. Except for the ITO layer, each layer is deposited by vacuum thermal evaporation.

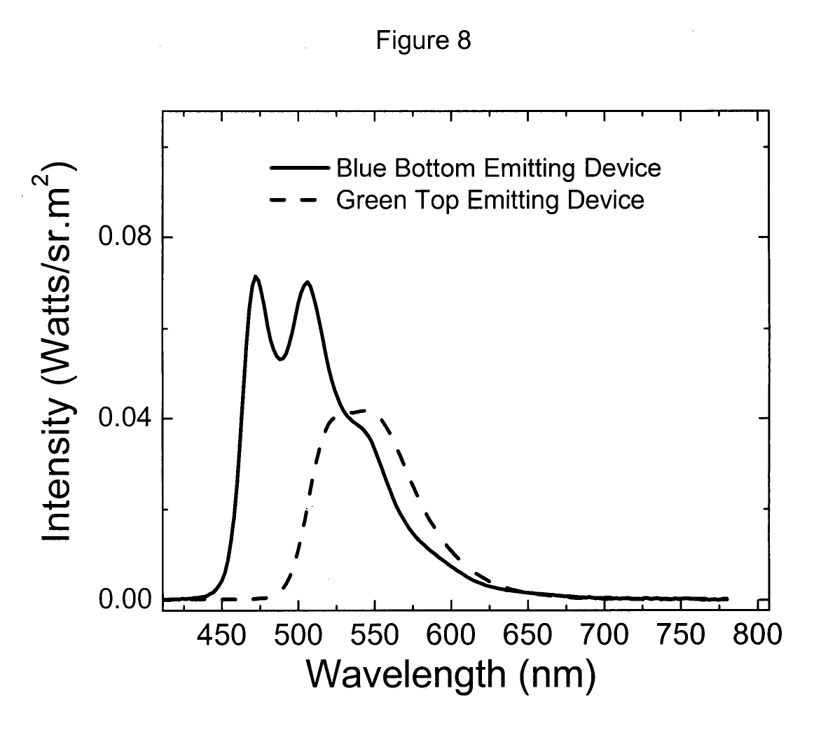

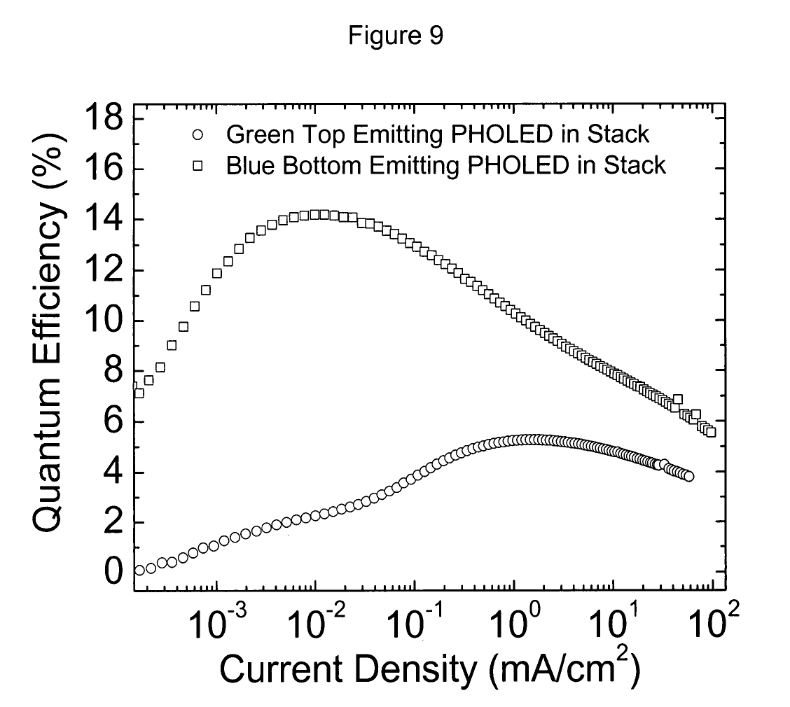

One device according to an embodiment of the present invention comprises a bottom emitting blue PHOLED and a top emitting green PHOLED. Intensity and efficiency curves for one example of such a device are shown in FIGS. 8 and 9, respectively. In this device, the organic stacks may be independently addressed or serially driven. The device successfully turns on, indicating that there are no shorts between electrodes.

FIGS. 8 and 9 show the electroluminescence and the external quantum efficiency for this device. The blue PHOLED has comparable efficiency to a standard single PHOLED. The green PHOLED has lower efficiency than a standard device because efficiency is not optimized; the Ca/Al top electrode causes optical absorption losses. Such losses can be overcome, for example, by using a more transparent top electrode.

While the present invention is described with respect to particular examples and preferred embodiments, it is understood that the present invention is not limited to these examples and embodiments. The present invention as claimed therefore includes variations from the particular examples and preferred embodiments described herein, as will be apparent to one of skill in the art.

What is claimed is:

1. An organic light emitting device comprising:
a) a first organic stack including a first organic emissive layer;
b) a second organic stack including a second organic emissive layer; and
c) a reflective conductive layer disposed between, and electrically connected to, the first organic stack and the second organic stack.

2. The device of claim 1, further comprising a transparent substrate upon one face of which the first organic stack, the reflective conductive layer, and the second organic stack are deposited.

3. The device of claim 2, wherein the reflective conductive layer is deposited by vacuum thermal evaporation.

4. The device of claim 2, further comprising:
a) the first organic stack further comprising:
i) a first end electrode;
ii) a hole injection layer;
iii) a hole transport layer;
iv) the first organic emissive layer;
v) an electron transport layer;
b) the reflective conductive layer;
c) the second organic stack further comprising:
i) a hole injection layer;
ii) a hole transport layer;
iii) the second organic emissive layer;
iv) a hole blocking layer;
v) an electron transport layer; and
vi) a second end electrode,
disposed, in that order, over the transparent substrate.

5. The device of claim 1, wherein the reflective conductive layer is a substrate, and wherein the first organic stack and the second organic stack are deposited on opposite faces of the reflective conductive layer.

6. The device of claim 1, further comprising a substrate, wherein both faces of the substrate includes a reflective conductive layer, and wherein the first organic stack and the second organic stack are deposited on opposite faces of the substrate.

7. The device of claim 6, wherein the substrate comprises two electrically connected substrate layers.

8. The device of claim 1, wherein the reflective conductive layer is a cathode for both the first organic stack and the second organic stack.

9. The device of claim 1, wherein the reflective conductive layer is an anode for both the first organic stack and the second organic stack.

10. The device of claim 1, wherein the reflective conductive layer is a cathode for the first organic stack and an anode for the second organic stack

11. The device of claim 1, wherein the reflective conductive layer is a charge generation layer.

12. The device of claim 1, wherein the first organic stack and the second organic stack are serially connected.

13. The device of claim 1, wherein the first organic stack and the second organic stack are connected in parallel.

14. The device of claim 1, wherein the first organic stack and the second organic stack are independently addressable.

15. The device of claim 1, wherein the first organic stack further comprises a first end electrode, and the second organic stack further comprises a second end electrode, wherein the first end electrode and the second end electrode are transparent.

16. The device of claim 15, wherein the device emits light in 4π steradians.

17. The device of claim 1, wherein the first organic stack and the second organic stack each further comprise one or more layers selected from the group consisting of injection layers, transport layers, and blocking layers.

18. The device of claim 1, wherein the first organic stack and the second organic stack are stacked vertically with respect to a substrate.

19. The device of claim 18, further comprising one or more additional organic stacks vertically stacked adjacent to the first organic stack or the second organic stack.

20. The device of claim 1, wherein the device is monochrome and has a fill factor of at least about 50% on each side of the reflective connecting electrode.

21. The device of claim 1, wherein the device is multi-color and has a fill factor of at least about 35% on each side of the reflective connecting electrode.

22. The device of claim 1, incorporated into a two-sided display.

23. The device of claim 1, incorporated into a illumination application.

24. The device of claim 1, wherein the reflective conductive layer is a metal film.

25. The device of claim 24, wherein the metal film has a maximum spike length of about 100 Å.

26. The device of claim 25, wherein the metal film has a maximum spike length of about 10 Å.

27. A method for making an organic light emitting device comprising:
a) fabricating a first organic stack over a substrate;
b) depositing a reflective conductive layer over the first organic stack; and
c) fabricating a second organic stack over the reflective connecting electrode,
wherein the reflective conductive layer is disposed between, and electrically connected to, the first organic stack and second organic stack.

28. The method of claim 27, wherein the reflective conductive layer is a metal film.

29. The method of claim 28, wherein depositing the reflective conductive layer is performed by vacuum thermal evaporation.

30. A method for making an organic light emitting device comprising:
a) fabricating a first organic stack on one face of a reflective conductive layer;
b) fabricating a second organic stack on the opposite face of a reflective conductive layer.

31. A method for making an organic light emitting device comprising:
a) fabricating a first organic stack on a reflective conductive layer attached to one face of a substrate; and
b) fabricating a second organic stack on a reflective conductive layer attached the opposite face of the substrate.
